(19) United States
(12) Patent Application Publication
(10) Pub. No.: US 2025/0283248 A1
(43) Pub. Date: Sep. 11, 2025

(54) EPITAXIAL GROWTH APPARATUS FOR SILICON CARBIDE SEMICONDUCTOR

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: HIROAKI FUJIBAYASHI, Nisshin-shi (JP); SHINICHI HOSHI, Nisshin-shi (JP); YUICHI TAKEUCHI, Kariya-city (JP); JUNICHI UEHARA, Kariya-city (JP); TAKUMI TSUNO, Kariya-city (JP)

(21) Appl. No.: 19/059,493

(22) Filed: Feb. 21, 2025

(30) Foreign Application Priority Data
Mar. 7, 2024 (JP) 2024-035004

(51) Int. Cl. C30B 25/14; C23C 16/32; C23C 16/44; C23C 16/455; C23C 16/458; C30B 25/10; C30B 25/12; C30B 25/20; H01L 21/67

(52) U.S. Cl. CPC C30B 25/14; C23C 16/325; C23C 16/4412; C23C 16/45565; C23C 16/4583; C30B 25/10; C30B 25/12; C30B 25/20; H01L 21/67017

(57) ABSTRACT

An epitaxial growth apparatus for a silicon carbide semiconductor, includes: a chamber providing an internal space; a susceptor disposed in the chamber and providing a placement surface for placing a silicon carbide semiconductor substrate thereon; a reaction vessel surrounding a periphery of the susceptor and providing a growth space for epitaxially growing a silicon carbide semiconductor layer on the silicon carbide semiconductor substrate; a first gas nozzle configured to introduce a silicon carbide source gas into the reaction vessel; a second gas nozzle disposed at a position away from the first gas nozzle and configured to introduce a dopant gas containing vanadium into the reaction vessel; a gas exhaust pipe configured to exhaust gas flowing out of the growth space from the chamber; and a heating device configured to heat the reaction vessel.

### CROSS REFERENCE TO RELATED APPLICATION

The present application claims the benefit of priority from Japanese Patent Application No. 2024-035004 filed on Mar. 7, 2024. The entire disclosures of the above application are incorporated herein by reference.

### TECHNICAL FIELD

The present disclosure relates to an epitaxial growth apparatus capable of epitaxially growing a silicon carbide (hereinafter referred to as SiC) semiconductor.

### BACKGROUND

Conventionally, it has been known an epitaxial growth apparatus for a SiC semiconductor layer that can dope both a p-type impurity and an n-type impurity. For example, an epitaxial growth apparatus includes a reaction vessel that provides a growth space, and first to fourth supply paths that supply various gases into the reaction vessel. The first supply path may supply a silicon (Si) source gas containing Si. The second supply path may supply a carbon (C) source gas containing C. The third supply path may supply a dopant gas of an n-type impurity. The fourth supply path may supply a dopant gas of a p-type impurity. Each of the first to fourth supply paths is provided with a mass flow controller (MFC) so as to enable the control of the flow rate of the gas flowing through the corresponding supply path. The first to fourth supply paths are joined together upstream of a gas nozzle that serves as a gas introduction pipe for the reaction vessel, so that the various gases are supplied into the reaction vessel through the single gas nozzle. Thus, a SiC semiconductor layer doped with the n-type impurity or the p-type impurity is epitaxially grown on a SiC semiconductor substrate placed in the reaction vessel.

### SUMMARY

The present disclosure describes a SiC semiconductor epitaxial growth apparatus for a silicon carbide semiconductor. According to an aspect, an epitaxial growth apparatus includes a chamber, a susceptor, a reaction vessel, a first gas nozzle, a second gas nozzle, a gas exhaust pipe, and a heating device. The chamber provides an internal space. The susceptor is disposed in the chamber and provides a placement surface for placing a silicon carbide semiconductor substrate thereon. The reaction vessel surrounds a periphery of the susceptor and provides a growth space for epitaxially growing a silicon carbide semiconductor layer on the silicon carbide semiconductor substrate. The first gas nozzle is configured to introduce a silicon carbide source gas into the reaction vessel. The second gas nozzle is disposed at a position away from the first gas nozzle and configured to introduce a dopant gas containing vanadium into the reaction vessel. The gas exhaust pipe is configured to exhaust gas flowing out of the growth space from the chamber. The heating device is configured to heat the reaction vessel.

### BRIEF DESCRIPTION OF DRAWINGS

Objects, features and advantages of the present disclosure will become more apparent from the following detailed description made with reference to the accompanying drawings, in which:

FIG. 1 is a cross-sectional view of an epitaxial growth apparatus according to a first embodiment of the present disclosure;

FIG. 2 is a cross-sectional view of an epitaxial growth apparatus according to a second embodiment of the present disclosure;

FIG. 3 is a cross-sectional view of an epitaxial growth apparatus according to a third embodiment of the present disclosure; and

FIG. 4 is a cross-sectional view of an epitaxial growth apparatus according to a fourth embodiment of the present disclosure.

### DETAILED DESCRIPTION

In an epitaxial growth apparatus of a related art in which supply paths for supplying various gases are joined together upstream of a gas nozzle that serves as a gas introduction pipe for the reaction vessel, in a case where a SiC semiconductor layer doped with vanadium (V) is formed, it has been confirmed that a V—Si product is formed in the nozzle that introduces various gases from the supply paths to the growth space, causing clogging of the nozzle. Specifically, in order to suppress the clogging of the nozzle according to SiC growth, it is necessary to keep the temperature at the outlet of the nozzle at 1400 degrees Celsius (° C.) or lower. However, in the case where the V is doped at the temperature of 1400° C. or lower, the V—Si product is generated.

The present disclosure provides an epitaxial growth apparatus for a SiC semiconductor, which is capable of suppressing the generation of V—Si product in a nozzle.

An epitaxial growth apparatus according to an aspect of the present disclosure includes: a chamber that provides an internal space; a susceptor that is disposed in the chamber and provides a placement surface for placing a SiC semiconductor substrate thereon; a reaction vessel that surrounds a periphery of the susceptor and provides a growth space for epitaxially growing a SiC semiconductor layer on the SiC semiconductor substrate; a first gas nozzle that is configured to introduce a source gas of SiC into the reaction vessel; a second gas nozzle that is disposed at a position away from the first gas nozzle and configured to introduce a dopant gas containing V into the reaction vessel; a gas exhaust pipe that is configured to exhaust gas flowing out of the growth space from the chamber; and a heating device that is configured to heat the reaction vessel.

In an epitaxial growth apparatus configured in such a manner, the source gas and the dopant gas containing V are introduced into the reaction vessel from separate nozzles. Therefore, even if the temperatures of the gas outlets of the first gas nozzle and the second gas nozzle are at 1400° C. or below, it is less likely that V—Si will be generated at the gas outlets. As such, it is possible to suppress the gas outlets of the first gas nozzle and the second gas nozzle from being clogged with the V—Si, when the SiC semiconductor layer is epitaxially grown.

Hereinafter, embodiments of the present disclosure will be described with reference to the drawings. In the following descriptions, the same or equivalent components will be denoted with the same reference numerals throughout the embodiments including the other embodiments.

### First Embodiment

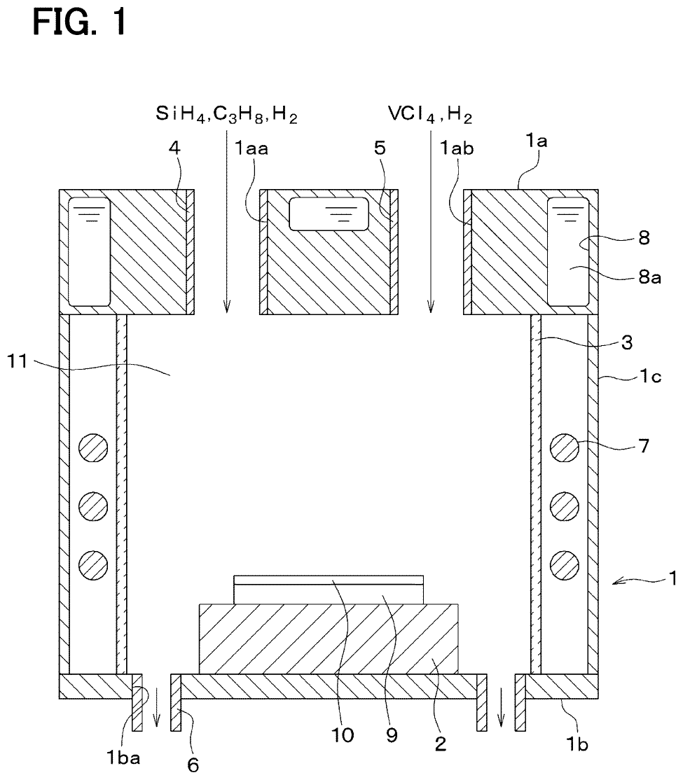

An epitaxial growth apparatus for a SiC semiconductor according to a first embodiment of the present disclosure will be described with reference to FIG. 1.

The epitaxial growth apparatus shown in FIG. 1 includes a chamber 1, a susceptor 2, a reaction vessel 3, a first gas nozzle 4, a second gas nozzle 5, a gas exhaust pipe 6, a heating device 7, a cooling unit 8, and the like. The epitaxial growth apparatus is configured to epitaxially grow a SiC semiconductor layer 10 on the surface of a SiC semiconductor substrate 9 disposed on the susceptor 2.

The chamber 1 has a hollow shape and includes a top surface 1a, a bottom surface 1b, and a side surface 1c. The susceptor 2, the reaction vessel 3 and the like are disposed in an internal space of the chamber 1. In the present embodiment, the chamber 1 has a generally cylindrical outer shape, with the top surface 1a and bottom surface 1b being circular, and the side surface 1c being cylindrical. The chamber 1 is made of any material that can withstand the temperatures experienced during the epitaxial growing. For example, the chamber 1 is made of a meal, such as a steel use stainless (SUS).

The top surface 1a is formed with a first opening 1aa and a second opening 1ab at positions separated from each other. The first gas nozzle 4 is disposed in the first opening 1aa, and the second gas nozzle 5 is disposed in the second opening 1ab. The bottom surface 1b is formed with an opening 1ba on a periphery of the susceptor 2. The gas exhaust pipe 6 is disposed in the opening 1ba of the bottom surface 1b. In FIG. 1, the openings 1ba are shown on both radial sides of the susceptor 2. For example, the bottom surface 1b may have multiple openings 1ba provided at multiple locations equally spaced apart in a circumferential direction around the susceptor 2. As another example, the bottom surface 1b may have the opening 1ba at only one location.

The susceptor 2 provides a placement surface for placing the SiC semiconductor substrate 9 thereon. The epitaxial growth is conducted on the SiC semiconductor substrate 9. In the present embodiment, the susceptor 2 is disposed at the center of the bottom surface 1b of the chamber 1, and the semiconductor substrate 9 is placed on the top surface of the susceptor 2 as the placement surface. The susceptor 2 is configured to be rotated by a rotation mechanism (not shown) during the epitaxial growing about a central axis, as a center of rotation, which is along a direction normal to the surface of the SiC semiconductor substrate 9 and passes through the center of the SiC semiconductor substrate 9. This allows the doping concentrations of impurities and the distribution of a film thickness of the grown SiC semiconductor layer 10 to be uniform. For example, the susceptor 2 is made of graphite, or made of graphite whose surface is coated with a high-melting point metal carbide such as tantalum carbide (TaC) or niobium carbide (NbC), or the whole of the susceptor 2 is made of the high-melting point metal carbide. It should be noted that the high-melting point metal carbide referred herein means a metal carbide that does not melt even at the temperature (for example, about 1600° C.) used for growing the SiC semiconductor layer 10.

The reaction vessel 3 is a wall member that divides the internal space of the chamber 1 so as to form a room into which gas is introduced. The reaction vessel 3 is disposed to surround the periphery of the susceptor 2 so as to form a growth space 11 in which epitaxial growth takes place. The reaction vessel 3 is made of graphite, or graphite whose surface is coated with a high-melting point metal carbide, such as TaC or NbC, or SiC. Alternatively, the whole of the reaction vessel 3 is made of the high-melting point metal carbide. In the present embodiment, the reaction vessel 3 has a cylindrical shape that is slightly smaller than the side surface 1c of the chamber 1 and is located inside the side surface 1c of the chamber 1 so that a space is provided between the reaction vessel 3 and the side surface 1c of the chamber 1.

A gap is provided between the inner wall surface of the reaction vessel 3 and the susceptor 2, and the opening 1ba and the gas exhaust pipe 6 are disposed in the gap. Therefore, the growth space 11 formed within the reaction vessel 3 is connected to the gas exhaust pipe 6 through the gap provided between the inner wall surface of the reaction vessel 3 and the susceptor 2.

The first gas nozzle 4 is a tubular member provided within the first opening 1aa formed in the upper surface 1a of the chamber 1. The first gas nozzle 4 is made of, for example, SUS or graphite. The first gas nozzle 4 introduces a Si source gas and a C source gas. The Si source gas is, for example, a silane-based gas such as SiH₄, and the C source gas is, for example, a propane-based gas such as C₃H₈. In this case, a carrier gas, such as hydrogen (H₂), is introduced through the first gas nozzle 4 together with the Si source gas and the C source gas. In the present embodiment, the first gas nozzle 4 is provided as the tubular member disposed within the first opening 1aa in the upper surface 1a of the chamber 1. Alternatively, the first gas nozzle 4 may be configured by the first opening 1aa.

The second gas nozzle 5 is also a tubular member disposed within the second opening 1ab formed in the upper surface 1a of the chamber 1. The second gas nozzle 5 is made of, for example, SUS or graphite. The second gas nozzle 5 introduces a dopant gas containing V, such as VCl₄. In this case, in addition to the dopant gas containing V, a carrier gas such as H₂ is introduced through the second gas nozzle 5. In the present embodiment, the second gas nozzle 5 is provided as the tubular member disposed within the second opening 1ab in the upper surface 1a of the chamber 1. Alternatively, the second gas nozzle 5 may be configured by the second opening 1ab.

By introducing the dopant gas containing V (hereinafter V dopant gas) in this manner, V is doped into the SiC semiconductor layer 10. V has an effect of suppressing degradation of electrical conduction of a diode included in a SiC semiconductor device, when the SiC semiconductor device including the diode is formed using the SiC semiconductor substrate 9 having the SiC semiconductor layer 10 formed thereon.

For example, a SiC semiconductor device including a switching element such as a metal oxide semiconductor field effect transistor (MOSFET) can be made using the SiC semiconductor substrate 9 having the SiC semiconductor layer 10 formed thereon. In such a case, a built-in diode is configured. When this SiC semiconductor device is applied to an inverter circuit or the like, and the built-in diode operates in bipolar mode due to the reflux operation during switching, there is a possibility that basal plane dislocations (hereinafter referred to as BPDs) will expand into Shockley stacking faults (hereinafter referred to as SSFs). That is, holes passing near the BPD recombine with electrons in the n-type layer, generating large recombination energy, which causes the BPD to expand into the SSF. Since the SSF occupies a larger area than the BPD and is a defect that is likely to cause degradation of the electrical characteristics of SiC semiconductor device, that is, degradation of the electrical conduction of the diode, it is desirable to suppress the expansion of the BPD into the SSF. V has the effect of suppressing the expansion of the BPD into the SSF.

The first gas nozzle 4 and the second gas nozzle 5 can be arranged at any location as long as they are spaced apart a specified distance or more from each other. In this case, the first gas nozzle 4 and the second gas nozzle 5 are arranged on opposite sides with respect to the center of the circular upper surface 1a in the radial direction and are equidistant from the center.

The gas exhaust pipe 6 is for exhausting unnecessary gas from the chamber 1. In the present embodiment, the gas exhaust pipe 6 is disposed on the bottom surface 1b of the chamber 1 and is configured to exhaust unreacted gases of the Si source gas and the C source gas, carrier gas and the like that flow out from the growth space 11.

The heating device 7 heats the reaction vessel 3 to raise the temperature of the growth space 11. The heating device 7 may be a device that performs heating by either a direct heating method or an induction heating method. In the case of the present embodiment, the heating device 7 is a device that performs heating by the direct heating method. The reaction vessel 3 is heated by the heating device 7, and an atmosphere in which the Si source gas and the C source gas introduced into the growth space 11 are thermally decomposed and the epitaxial growth is conducted is formed.

Further, the epitaxial growth apparatus is provided with the cooling unit 8 for cooling the first gas nozzle 4 and the second gas nozzle 5. In the present embodiment, the cooling unit 8 is configured by incorporating a flow path through which cooling water 8a flows in the upper surface 1a of the chamber 1. For example, the cooling unit 8 is arranged to surround the first gas nozzle 4 and the second gas nozzle 5 and to pass between the first gas nozzle 4 and the second gas nozzle 5. However, the cooling unit 8 is arranged in any layout as long as the temperature at least in the vicinity of the first gas nozzle 4 is kept at 1400° C. or lower.

In this manner, the epitaxial growth apparatus for a SiC semiconductor according to the present embodiment is configured. In the epitaxial growth apparatus configured in this manner, to epitaxially grow the SiC semiconductor layer 10, the reaction vessel 3 is heated by the heating device 7 so that the SiC semiconductor substrate 9 is heated to, for example, 1600 to 1750° C. At this time, the gas outlets of the first gas nozzle 4 and the second gas nozzle 5 may be heated by radiant heat from the reaction vessel 3, the SiC semiconductor substrate 9 and the like. However, the temperatures of the gas outlets are kept at 1400° C. or lower, for example, in the range of 500 to 1200° C. As a result, it is possible to suppress the gas outlets of the first gas nozzle 4 and the second gas nozzle 5 from being blocked by SiC growth.

On the other hand, the temperature being 1400° C. or lower causes the generation of the V—Si. In the present embodiment, however, the Si source gas and the C source gas are introduced from the first gas nozzle 4, and the V dopant gas is introduced from the second gas nozzle 5 located away from the first gas nozzle 4. In this way, since the Si source gas and the V dopant gas are introduced from separate gas nozzles, even if the temperatures of the gas outlets of the first gas nozzle 4 and the second gas nozzle 5 are at 1400° C. or lower, the generation of V—Si at the gas outlets can be suppressed.

Therefore, when the SiC semiconductor layer 10 is epitaxially grown, the gas outlets of the first gas nozzle 4 and the second gas nozzle 5 can be suppressed from being blocked by the V—Si product. As a result, it is possible to grow the SiC semiconductor layer 10 stably.

### Second Embodiment

A second embodiment of the present disclosure will be described. In the present embodiment, the number of gases introduced from the first gas nozzle 4 is increased from that in the first embodiment, as well as the number of gas nozzles is increased from that in the first embodiment. The other configurations of the present embodiment are similar to those of the first embodiment. Thus, only the differences from the first embodiment will be described hereinafter.

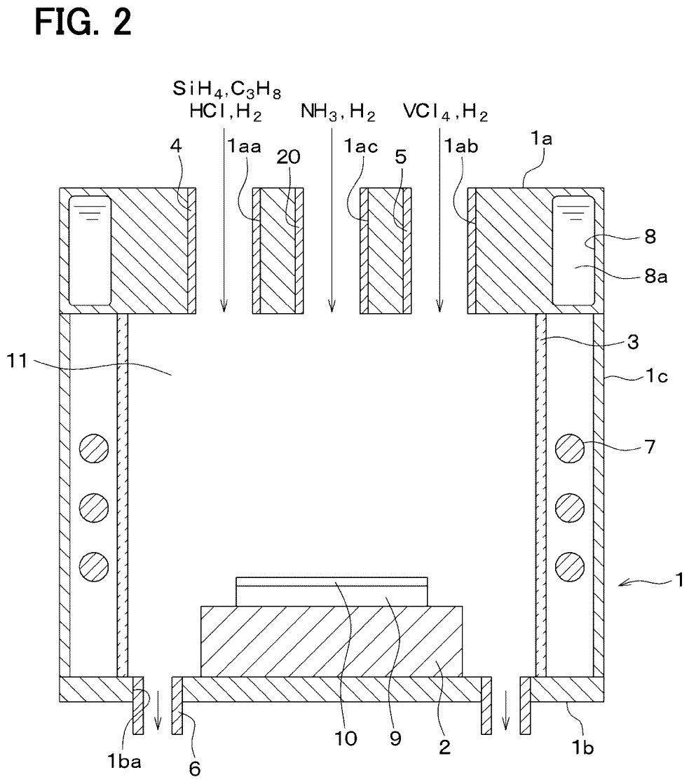

As shown in FIG. 2, in the present embodiment, the Si source gas, the C source gas, the carrier gas, and HCl serving as an etching gas are introduced from the first gas nozzle 4. By introducing the etching gas in addition to the Si source gas and the C source gas, it is possible to further suppress generation of SiC polycrystals or the like in the first gas nozzle 4.

In addition to the first gas nozzle 4 and the second gas nozzle 5, a third gas nozzle 20 is provided. The third gas nozzle 20 may be arranged in any position. In this case, however, the third gas nozzle 20 is arranged between the first gas nozzle 4 and the second gas nozzle 5. In other words, the third gas nozzle 20 is arranged closest to the center of the upper surface 1a of the chamber 1, and the first gas nozzle 4 and the second gas nozzle 5 are disposed on outer sides of the third gas nozzle 20, that is, disposed more to outside than the third gas nozzle 20.

A third opening 1ac is formed in the upper surface 1a of the chamber 1, in addition to the first opening 1aa and the second opening 1ab. The third gas nozzle 20 is a tubular member provided within the third opening 1ac, and is made of, for example, SUS or graphite. The third gas nozzle 20 introduces NH₃ as an n-type dopant gas containing N as an n-type impurity. In this case, a carrier gas, such as H₂, is introduced through the third gas nozzle 20 together with NH₃, which serves as the n-type dopant gas.

In this manner, when the n-type dopant gas is introduced, the third gas nozzle 20 is provided separately from the first gas nozzle 4 and the second gas nozzle 5, and the n-type dopant gas is introduced from the third gas nozzle 20. In the case where NH₃ is used as the n-type dopant gas, if the gas introduced from the first gas nozzle 4 contains Cl element, or if VCl₄ containing Cl element is used as the V dopant gas, NH₄Cl may be generated in the gas nozzle, causing the clogging of the gas nozzle. In the present embodiment, however, these gases are introduced from separate gas nozzles, namely, from the first gas nozzle 4, the second gas nozzle 5, and the third gas nozzle 20, which are disposed separately from each other. Therefore, by separating the first gas nozzle 4 and the second gas nozzle 5 from each other, the generation of V—Si can be suppressed. Furthermore, by separating the third gas nozzle 20 from the first gas nozzle 4 and the second gas nozzle 5, the generation of NH₄Cl can also be suppressed.

Therefore, when the SiC semiconductor layer 10 is epitaxially grown, it is possible to suppress the clogging of the gas outlet of each gas nozzle with V—Si products or NH₄Cl. As a result, it is possible to grow the SiC semiconductor layer 10 stably.

In the present embodiment, the gas introduced from the first gas nozzle 4 contains Cl element, and HCl serving as an etching gas is introduced as an example. As another example, there is a case where a chlorosilane such as SiHCl₃ is used as a SiC source gas. It is effective to suppress the generation of NH₄Cl, when the Cl element is contained either in the gas introduced from the first gas nozzle 4, which introduces the Si source gas and the C source gas, that is, the gas for the SiC source or in the gas introduced together with the gas for the SiC source. In the present embodiment, the example in which both the gas introduced from the first gas nozzle 4 and the gas introduced from the second gas nozzle 5 contain the Cl element has been described. However, it is preferable to suppress the generation of NH₄Cl even if the Cl element is contained in only one of the gas introduced from the first gas nozzle 4 and the gas introduced from the second gas nozzle 5.

### Third Embodiment

A third embodiment of the present disclosure will be described. In the present embodiment, the configuration of the second gas nozzle 5 is changed from those of the first and second embodiments. The other configurations are similar to those of the first and second embodiments. Therefore, only the parts that are different from the first and second embodiments will be described hereinafter. Here, the configuration of the present embodiment is applied to an epitaxial growth apparatus having the third gas nozzle 20 as the second embodiment as an example. On the other hand, the configuration of the present embodiment can be applied to an epitaxial growth apparatus without having the third gas nozzle 20 as the first embodiment.

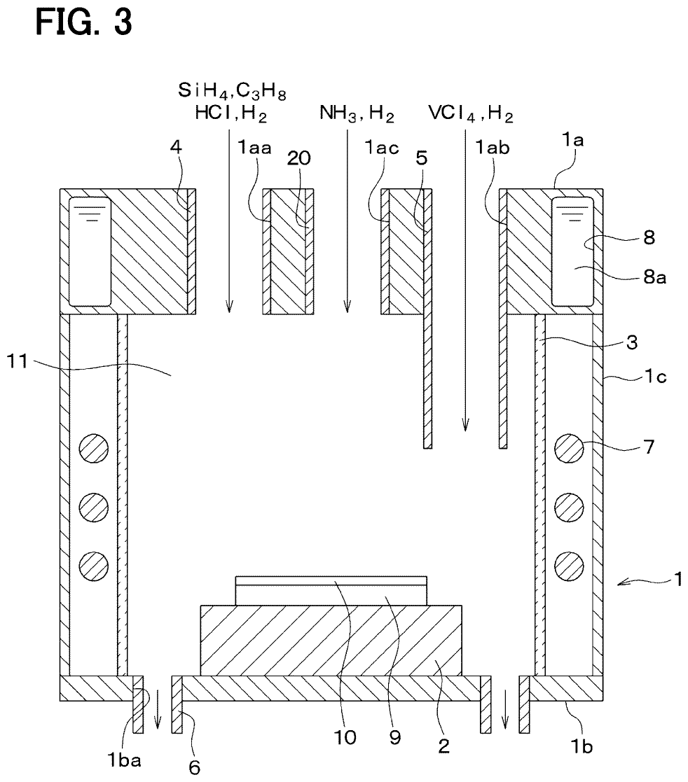

As shown in FIG. 3, in the epitaxial growth apparatus of the present embodiment, the gas outlet of the second gas nozzle 5 is located lower than the gas outlets of the first gas nozzle 4 and the third gas nozzle 20. That is, the gas outlet of the second gas nozzle 5 is located closer to the susceptor 2 than the gas outlets of the first gas nozzle 4 and the third gas nozzle 20. In other words, the second gas nozzle 5 is extended toward the higher temperature side. Preferably, the second gas nozzle 5 is disposed on an outer peripheral portion of the upper surface 1a, that is, at a position closer to the reaction vessel 3, so that the portion of the second gas nozzle 5 protruding from the upper surface 1a extends along the inner wall surface of the reaction vessel 3. More preferably, the lower end of the second gas nozzle 5 is arranged in the vicinity of the portion of the reaction vessel 3 where the heating device 7 is arranged. For example, when viewed in the horizontal direction, the lower end of the second gas nozzle 5 is positioned lower than the upper end of the heating device 7 so that the upper end of the heating device 7 and the gas outlet of the second gas nozzle 5 overlap with each other.

In this case, it is possible to further separate the V dopant gas from the Si source gas. As a result, it is possible to further suppress the generation of V—Si, and to further suppress the clogging of each gas nozzle with the V—Si product. In addition, since the second gas nozzle 5, through which the V dopant gas is introduced, is extended to the higher temperature side so that the mixing position of V and Si is at a higher temperature position, the generation of V—Si can be further suppressed. In particular, the second gas nozzle 5 is disposed more to outside than the third gas nozzle 20 and closer to the heating device 7. Therefore, it is possible to heat the second gas nozzle more easily 5 to a higher temperature.

### Fourth Embodiment

A fourth embodiment of the present disclosure will be described. In the present embodiment, in comparison with the third embodiment, the gases introduced from the first gas nozzle 4 and the second gas nozzle 5 are mixed and then introduced into the growth space 11. The other configurations of the present embodiment are similar to those of the first and second embodiments. Therefore, only the parts that are different from the third embodiment will be described.

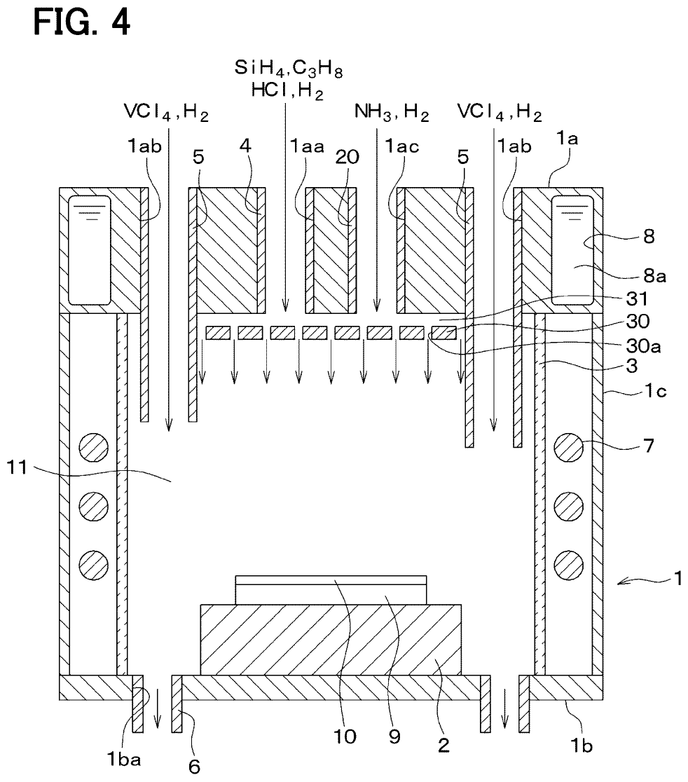

As shown in FIG. 4, in the present embodiment, the second gas nozzle 5 is disposed more to outside than the first gas nozzle 4 and the third gas nozzle 20 in the upper surface 1a of the chamber 1. Also in the present embodiment, the second gas nozzle 5 is extended downward, as the third embodiment. Further, the second gas nozzles 5 are provided at multiple locations on the outer periphery of the first gas nozzle 4 and the third gas nozzle 20 in the top surface 1a. A shower plate 30 serving as a partition plate having a plurality of holes 30a is provided below the gas outlets of the first gas nozzle 4 and the third gas nozzle 20, which are provided more to inside than the second gas nozzles 5. For this reason, a mixing space 31 is formed above the growth space 11. The Si source gas and the C source gas from the first gas nozzle 4 can be mixed with the dopant gas containing the element as an impurity from the third gas nozzle 20 within the mixing space 31, thereby to produce a mixed gas. The mixed gas is introduced into the growth space 11 in a shower-like manner through the multiple holes 30a formed in the shower plate 30. Therefore, it is possible to supply each element with uniform distribution over the surface of the SiC semiconductor substrate 9.

By introducing the gases as the mixed gas into the growth space 11 in this manner, the film thickness and carrier concentration of the SiC semiconductor layer 10 can be made more uniform.

In general, epitaxially grown films require high uniformity, such as a thickness of ±10% and a carrier concentration of ±15%. On the other hand, if the impurity concentration of V is 1×10¹⁴ cm⁻³ or more, the effect of suppressing deterioration of electrical conduction of the diode can be expected. If the impurity concentration of V is too high, defects may occur. However, if the impurity concentration of V is 1×10¹⁶ cm⁻³ or less, the occurrence of defects can be suppressed. In other words, if the impurity concentration of V is 1×10¹⁴ cm⁻³ or more and 1×10¹⁶ cm⁻³ or less, the effect of suppressing deterioration of electrical conduction of the diode as well as the effect of suppressing defects are achieved. Since the setting range of such impurity concentration of V is wide and easily adjustable, there is no need to uniformly introduce the gas containing V using the shower plate 30. Therefore, the gas containing V can be introduced to a position where the gas outlet is at a higher temperature without passing through the shower plate 30, while the Si source gas and the like can be introduced uniformly through the shower plate 30.

### OTHER EMBODIMENTS

While the present disclosure has been described in accordance with the embodiments described above, the present disclosure is not limited to the embodiments described above and includes various modifications and equivalent modifications. In addition, various combinations and configurations, as well as other combinations and configurations that include only one element, more, or less, fall within the scope and spirit of the present disclosure.

In the first to fourth embodiments described above, the shapes of the chamber 1, susceptor 2, reaction vessel 3, and the like and the types of gases introduced from each gas nozzle are merely examples, and other shapes and other types of gases may be used. In the second and third embodiments described above, the case where an n-type dopant is introduced, that is, the case where the SiC semiconductor layer 10 is made as n-type has been described as an example. This is merely one example, and even in the case where a p-type dopant is introduced to make the SiC semiconductor layer 10 the p-type, the epitaxial growth apparatus having the configuration in each of the embodiments described above can be provided. Examples of the p-type dopant gas include trimethylaluminium (TMA) gas and B₂H₆. In the embodiments described above, the first gas nozzle 4 is a single gas nozzle for introducing both the Si source gas and the C source gas. As another example the first gas nozzle 4 may be separated into two gas nozzles, one for introducing the Si source gas and the other for introducing the C source gas.

In each of the embodiments described above, the structure in which the reaction vessel 3 is provided inside the chamber 1 and the chamber 1 and the reaction vessel 3 are configured as separate members. Alternatively, the chamber 1 itself may be configured to constitute the reaction vessel 3. In other words, as long as the reaction vessel 3 surrounds the susceptor 2 to form the growth space 11, it does not matter whether the reaction vessel 3 is formed by the chamber 1 itself or is separate from the chamber 1.

What is claimed is:

1. An epitaxial growth apparatus for a silicon carbide semiconductor, comprising:
a chamber providing an internal space;
a susceptor disposed in the chamber and providing a placement surface for placing a silicon carbide semiconductor substrate thereon;
a reaction vessel surrounding a periphery of the susceptor and providing a growth space for epitaxially growing a silicon carbide semiconductor layer on the silicon carbide semiconductor substrate;
a first gas nozzle configured to introduce a silicon carbide source gas into the reaction vessel;
a second gas nozzle disposed at a position away from the first gas nozzle and configured to introduce a dopant gas containing vanadium into the reaction vessel;
a gas exhaust pipe configured to exhaust gas flowing out of the growth space from the chamber; and
a heating device configured to heat the reaction vessel.

2. The epitaxial growth apparatus according to claim 1, wherein
the second gas nozzle has a gas outlet extended closer to the susceptor than a gas outlet of the first gas nozzle.

3. The epitaxial growth apparatus according to claim 1, further comprising:
a third gas nozzle disposed at a position away from the first gas nozzle and the second gas nozzle and configured to introduce a dopant gas containing an element serving as an n-type or p-type impurity for the silicon carbide semiconductor layer.

4. The epitaxial growth apparatus according to claim 3, wherein
the chamber has a hollow shape, and includes a top surface, a bottom surface, and a side surface,
the first gas nozzle, the second gas nozzle, and the third gas nozzle are disposed at different positions in the top surface of the chamber, and
the second gas nozzle is located at a position more to outside than the third gas nozzle in the top surface of the chamber.

5. The epitaxial growth apparatus according to claim 4, wherein
the second gas nozzle is located at a position more to outside than the first gas nozzle and the third gas nozzle in the top surface of the chamber,
the epitaxial growth apparatus further comprising:
a shower plate disposed below a gas outlet of the first gas nozzle and a gas outlet of the third gas nozzle, as a partition plate, to provide a mixing space at an upper portion of the growth space, the shower plate having a plurality of holes, wherein
the shower plate is configured so that the source gas introduced from the first gas nozzle and the dopant gas containing the element serving as the n-type or p-type impurity introduced from the third gas nozzle are mixed in the mixing space and then introduced into the growth space through the plurality of holes, and
the second gas nozzle is configured to introduce the dopant gas containing the vanadium into the growth space without passing through the mixing space.
